(19) United States
(12) Patent Application Publication
(10) Pub. No.: US 2026/0162945 A1
(43) Pub. Date: Jun. 11, 2026

(54) WAFER PLACEMENT TABLE

(71) Applicant: NGK INSULATORS, LTD., Nagoya-shi (JP)

(72) Inventors: Taro USAMI, Ginan-town (JP); Tatsuya KUNO, Nagoya-shi (JP)

(21) Appl. No.: 19/399,892

(22) Filed: Nov. 25, 2025

Related U.S. Application Data
(63) Continuation of application No. PCT/JP2025/019619, filed on May 30, 2025.

(30) Foreign Application Priority Data
Nov. 6, 2024 (JP) 2024-194356

(51) Int. Cl. H01J 37/32; H10P 72/76

(52) U.S. Cl. CPC H01J 37/32642; H10P 72/7616; H01J 2237/334

(57) ABSTRACT

A wafer placement table includes a ceramic body having a wafer placement surface and a focus ring placement surface located radially outside the wafer placement surface, the ceramic body having an electrode built therein; a focus ring having conductive and placed on the focus ring placement surface; a plug disposition hole located below the focus ring and penetrating the ceramic body; and a plug provided in the plug disposition hole and allowing gas to pass through an interior thereof, wherein the focus ring has a lower surface, and the lower surface has a recessed portion for pooling gas at a position opposed to the plug, and an upper surface of the plug is disposed within the recessed portion and is located at a position higher than the lower surface of the focus ring.

### CROSS-REFERENCE TO RELATED APPLICATION

This application is a continuation application of PCT/JP2025/019619, filed on May 30, 2025, which claims the benefit of priority from Japanese Patent Application No. 2024-194356, filed on November 6, 2024, the entire contents of which are incorporated herein by reference.

### BACKGROUND OF THE INVENTION

### 1. Field of the Invention

The present invention relates a wafer placement table.

### 2. Description of the Related Art

Hitherto, a wafer placement table used in semiconductor manufacturing apparatuses has been known. For example, the wafer placement table disclosed in PTL 1 includes a substrate stage for placing a wafer to be processed, and a focus ring placed on the substrate stage so as to surround the wafer. A heat-transfer-gas groove is provided on the upper surface of the portion of the substrate stage on which the focus ring is placed. By supplying a heat transfer gas such as helium to this heat-transfer-gas groove via a gas introduction tube that penetrates the substrate stage vertically, heat conduction between the focus ring and the substrate stage can be promoted and the temperature of the focus ring can be adjusted.

### CITATION LIST

### PATENT LITERATURE

PTL 1: JP 5357639 B

### SUMMARY OF THE INVENTION

However, as in PTL 1, in a space (the heat-transfer-gas groove) formed in the portion of the substrate stage on which the focus ring is placed, discharge may occur when plasma for processing the wafer is generated.

The present invention was made to solve such a problem, and its main object is to suppress discharge in a space for pooling gas between the focus ring and a ceramic body.

The present invention employs the following configuration to achieve the above-described main object.

[1] A wafer placement table of the present invention is a wafer placement table including: a ceramic body having a wafer placement surface and a focus ring placement surface located radially outside the wafer placement surface, the ceramic body having an electrode built therein; a focus ring having conductive and placed on the focus ring placement surface; a plug disposition hole located below the focus ring and penetrating the ceramic body; and a plug provided in the plug disposition hole and allowing gas to pass through an interior thereof, wherein the focus ring has a lower surface, and the lower surface has a recessed portion for pooling gas at a position opposed to the plug, and an upper surface of the plug is disposed within the recessed portion and is located at a position higher than the lower surface of the focus ring.

In this wafer placement table, the plug allowing gas to pass through the interior thereof is provided in the plug disposition hole that is located below the focus ring having conductive and is penetrating the ceramic body. The focus ring has the lower surface, and the lower surface has the recessed portion for pooling gas at the position opposed to the plug. The upper surface of the plug is disposed within the recessed portion and is located at the position higher than the lower surface of the focus ring. In this way, because the recessed portion for pooling gas supplied via the plug is located on the inside of the electrically conductive focus ring, a potential of the space within the recessed portion during use of the wafer placement table becomes the same as, or close to, a potential of the focus ring, thereby reducing the potential difference within the space. Accordingly, in the space within the recessed portion, that is, in the space for pooling gas between the focus ring and the ceramic body, discharge can be suppressed.

[2] In the wafer placement table described above (the wafer placement table according to [1]), a bottom surface of the recessed portion may be at a position lower than the wafer placement surface. In this manner, a height from an upper surface of the focus ring to the bottom surface of the recessed portion becomes sufficiently large. Accordingly, when an upper-surface side of the focus ring wears due to use of the wafer placement table, exposure of the recessed portion on the upper-surface side can be suppressed.

[3] In the wafer placement table described above (the wafer placement table according to [1] or [2]), the recessed portion may include an annular groove provided radially outside the wafer placement surface, the plug disposition hole and the plug may be each provided in plurality below the focus ring, and the upper surface of each of the plurality of plugs may be disposed within the recessed portion. In this manner, compared with a case where a plurality of recessed portions are provided discretely for the respective plurality of plugs, providing the recessed portion with an annular groove enables improved heat conduction between the focus ring and the ceramic body through the gas within the recessed portion.

[4] In the wafer placement table described above (the wafer placement table according to [3]), the recessed portion may include one or more hole portions having a width narrower than that of the annular groove and having a bottom surface located higher than a bottom surface of the annular groove, and the upper surface of each of the plurality of plugs may be disposed within the one or more hole portions. Here, for example, if the recessed portion has only the annular groove, widening the annular groove can further improve heat conduction between the focus ring and the ceramic body through the gas within the recessed portion, but it tends to increase a space volume within the recessed portion and make discharge within the recessed portion more likely. In contrast, by providing the recessed portion with both the annular groove that have a wide with and have the bottom surface located at a low position and one or more hole portions that have a narrow width and have the bottom surface located at a high position, the groove depth can be made shallower while allowing a plug to be disposed in the recessed portion, thereby reducing the space volume within the recessed portion. Thus, discharge within the recessed portion can be suppressed while further improving heat conduction between the focus ring and the ceramic body.

[5] In the wafer placement table described above (the wafer placement table according to [4]), the one or more hole portions may be provided in plurality in correspondence with each of the plurality of plugs, and the upper surface of each of the plurality of plugs may be disposed within a corresponding one of the hole portions.

[6] In the wafer placement table described above (the wafer placement table according to any one of [1] to [5]), the plug may have a hole in the upper surface thereof, and the focus ring may have a protruding portion that protrudes downward within the recessed portion and is inserted into the hole. In this manner, because a lower end of the protruding portion of the focus ring is located lower than the upper surface of the plug and inside the plug, a potential difference is less likely to arise in a space around the upper surface of the plug, and discharge within the recessed portion can be further suppressed.

[7] The wafer placement table described above (the wafer placement table according to any one of [1] to [6]) may further include an auxiliary member disposed between a side surface of a portion of the plug that is disposed within the recessed portion and a side surface of the recessed portion. In this manner, the presence of the auxiliary member can reduce a space volume between the side surface of the plug within the recessed portion and the side surface of the recessed portion. Accordingly, discharge within the recessed portion can be further suppressed.

[8] In the wafer placement table described above (the wafer placement table according to [7]), the auxiliary member may be also present between the upper surface of the plug and a bottom surface of the recessed portion. In this manner, not only the space volume between the side surface of the plug within the recessed portion and the side surface of the recessed portion but also a space volume between the upper surface of the plug and the bottom surface of the recessed portion can be reduced. Accordingly, discharge within the recessed portion can be further suppressed.

[9] In the wafer placement table described above (the wafer placement table according to [7] or [8]), the auxiliary member may allow gas to pass through an interior thereof. In this manner, gas that has passed through the plug can be readily distributed in the space within the recessed portion.

[10] In the wafer placement table described above (the wafer placement table according to any one of [7] to [9]), the auxiliary member may have conductive and may be electrically continuous with the focus ring. In this manner, because the auxiliary member becomes at the same potential as the focus ring, the potential difference within the space in the recessed portion can be further reduced, thereby further suppressing discharge within the recessed portion.

[11] In the wafer placement table described above (the wafer placement table according to any one of [7] to [10] ), the plug disposition hole and the plug may be each provided in plurality below the focus ring, and the recessed portion and the auxiliary member may be each provided in plurality in one-to-one correspondence with the plurality of plugs.

### BRIEF DESCRIPTION OF THE DRAWINGS

FIG. 1 is a vertical cross-sectional view of a wafer placement table 10.

FIG. 2 is a partial enlarged view of FIG. 1.

FIG. 3 is a plan view of a ceramic body 20 as seen from above.

FIG. 4 is a plan view of a focus ring 60 as seen from below.

FIGS. 5A to 5C are manufacturing process diagrams for the wafer placement table 10.

FIG. 6 is a partially enlarged view of a vertical cross-section of a wafer placement table 110.

FIG. 7 is a plan view of a focus ring 160 as seen from below.

FIG. 8 is a partially enlarged view of a vertical cross-section of a wafer placement table 210.

FIG. 9 is a partially enlarged view of a vertical cross-section of a wafer placement table 310.

FIG. 10 is a partially enlarged view of a vertical cross-section of a wafer placement table 410.

FIG. 11 is a plan view of the focus ring 60 and an auxiliary member 470 as seen from below.

FIG. 12 is a partially enlarged view of a vertical cross-section of a wafer placement table 510.

FIG. 13 is a partially enlarged view of a vertical cross-section of a wafer placement table 610.

FIG. 14 is a partially enlarged view of a vertical cross-section of a wafer placement table 710.

FIG. 15 is a plan view of the focus ring 160 and an auxiliary member 770 as seen from below.

FIG. 16 is a partially enlarged view of a vertical cross-section of a wafer placement table 810.

FIG. 17 is a plan view of the focus ring 160 and an auxiliary member 870 as seen from below.

### DETAILED DESCRIPTION OF THE INVENTION

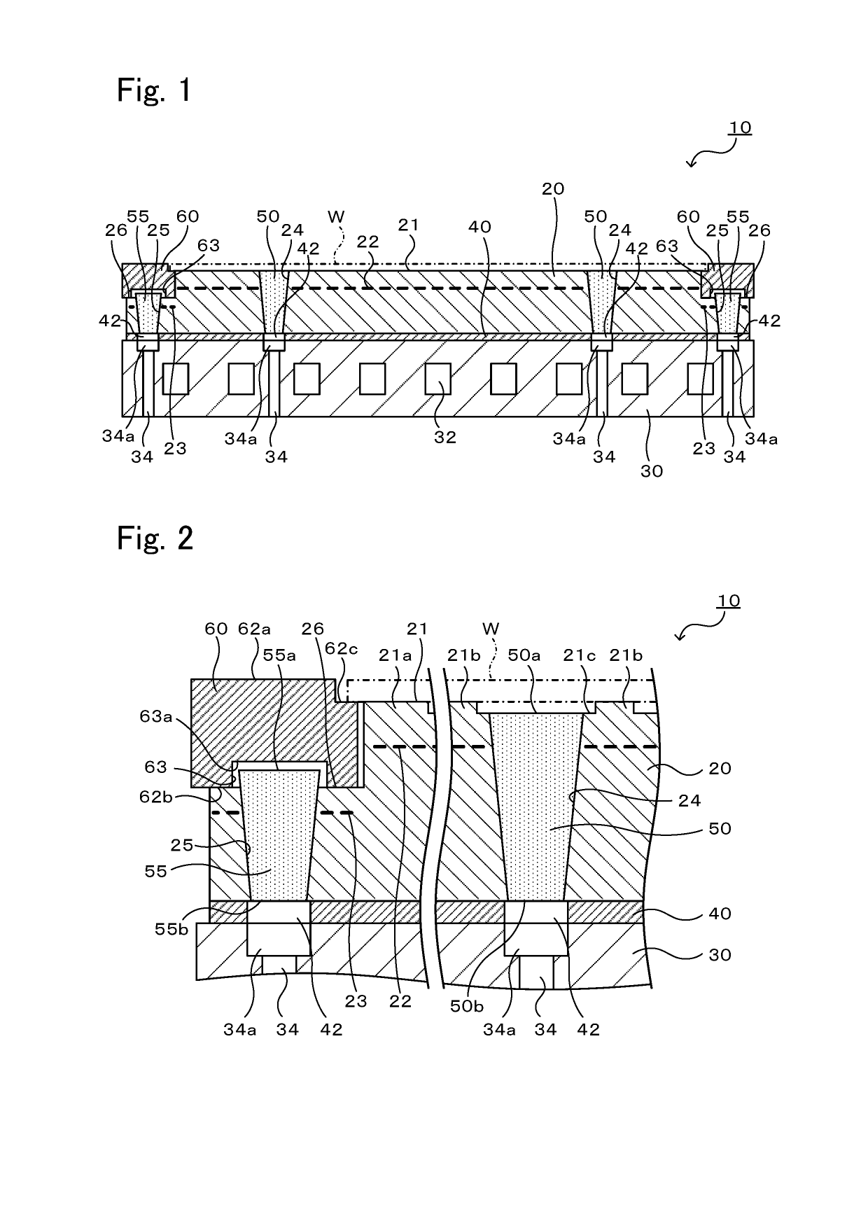

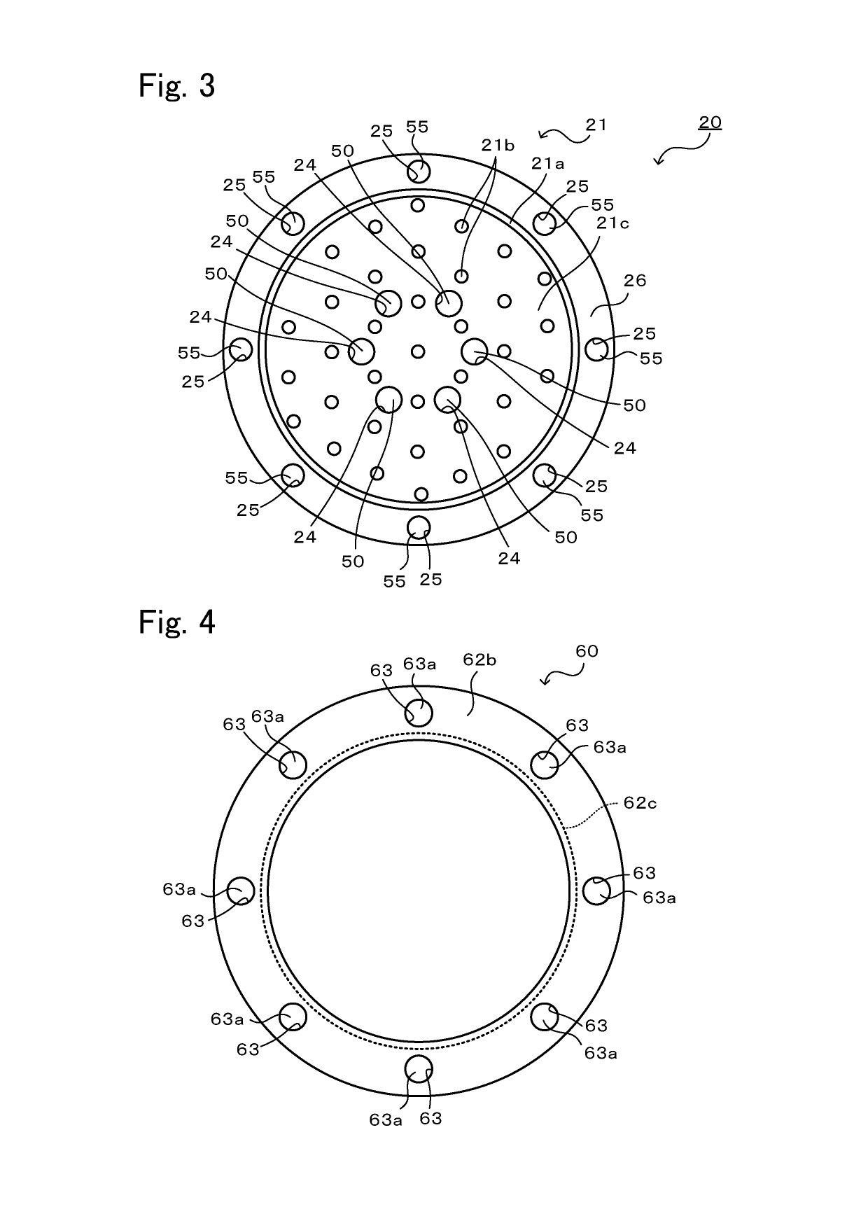

An embodiment of the present invention will be described using the drawings. FIG. 1 is a vertical cross-sectional view of a wafer placement table 10 according to an embodiment of the present invention. FIG. 2 is an partial enlarged view of FIG. 1. FIG. 3 is a plan view of a ceramic body 20 as seen from above. FIG. 4 is a plan view of a focus ring 60 as seen from below.

The wafer placement table 10 includes a ceramic body 20, a base plate 30, a metal joint layer 40, a central plug 50, an outer peripheral plug 55, and a focus ring 60.

The ceramic body 20 is a ceramic disk (for example, with a diameter of 300 mm) such as an alumina sintered body or an aluminum nitride sintered body. The ceramic body 20 is preferably dense. The dense means a porosity of 5% or less (preferably 3% or less, more preferably 1% or less). The porosity of the ceramic body 20 is the open porosity measured in accordance with JIS R1634:1998. The thickness of the ceramic body 20 is, for example, 1 mm to 5 mm. The ceramic body 20 has, on its upper surface, a wafer placement surface 21 and a focus ring (FR) placement surface 26. The wafer placement surface 21 is a surface having a circular outer edge on which a wafer W is placed. As shown in FIGS. 2 and 3, an annular seal band 21a and a plurality of circular small projections 21b formed inward of the seal band 21a are formed on the upper surface of the ceramic body 20. A portion in a region inward of the seal band 21a where no circular small projections 21b are provided is referred to as a reference surface 21c. The seal band 21a and the circular small projections 21b have the same height, and their height from the reference surface 21c is, for example, several μm to several tens of μm. The upper surface of the seal band 21a and the upper surfaces of the circular small projections 21b constitute the wafer placement surface 21. The FR placement surface 26 is an annular surface provided on the outer peripheral side of, and at a lower height than, the wafer placement surface 21. A stepped portion is provided between the FR placement surface 26 and the wafer placement surface 21 in the ceramic body 20, whereby the height of the FR placement surface 26 is one step lower than the height of the wafer placement surface 21. The height of the FR placement surface 26 is lower than the reference surface 21c. The annular focus ring 60 is placed on the FR placement surface 26.

The ceramic body 20 has a first electrode 22 and a second electrode 23 built therein. The first electrode 22 and the second electrode 23 are mesh electrodes that is used as electrostatic electrodes and that have flat plate shapes and are connected to an external DC power supply via a power-feeding member (not shown). A low-pass filter may be disposed in the middle of the power-feeding member. The power-feeding member is electrically insulated from the metal joint layer 40 and the base plate 30. The first electrode 22 is disposed, from a top view, in a region inward of the outer edge of the wafer placement surface 21 (that is, the outer edge of the seal band 21a). The second electrode 23 is disposed outside the first electrode 22 and is positioned so as to overlap the FR placement surface 26 from a top view. When the direct voltage is applied to the first electrode 22, the wafer W is attracted and secured to the wafer placement surface 21 due to electrostatic attraction force, and when applying the direct voltage ends, the wafer W that is attracted and secured to the wafer placement surface 21 is released. When the direct voltage is applied to the second electrode 23, the focus ring 60 is attracted and secured to the FR placement surface 26 due to electrostatic attraction force, and when applying the direct voltage ends, the focus ring 60 that is attracted and secured to the FR placement surface 26 is released.

The ceramic body 20 has a central-plug disposition hole 24 and an outer-peripheral-plug disposition hole 25. Both the central-plug disposition hole 24 and the outer-peripheral-plug disposition hole 25 are holes penetrating the ceramic body 20 in the up-down direction. The central-plug disposition hole 24 is a through hole extending from the lower surface of the ceramic body 20 to the reference surface 21c. Although the central-plug disposition hole 24 penetrates the first electrode 22 in the up-down direction, the first electrode 22 is not exposed on an inner peripheral surface of the central-plug disposition hole 24. The outer-peripheral-plug disposition hole 25 is a through hole extending from the lower surface of the ceramic body 20 to the FR placement surface 26. Although the outer-peripheral-plug disposition hole 25 penetrates the second electrode 23 in the up-down direction, the second electrode 23 is not exposed on an inner peripheral surface of the outer-peripheral-plug disposition hole 25. Both the central-plug disposition hole 24 and the outer-peripheral-plug disposition hole 25 face gas holes 34 of the base plate 30. Both the central-plug disposition hole 24 and the outer-peripheral-plug disposition hole 25 are spaces whose cross-sectional area decreases from the respective upper openings toward the respective lower openings (for example, having an inverted frustoconical shape). As shown in FIG. 3, the central-plug disposition holes 24 are provided at a plurality of positions (for example, a plurality of locations at equal intervals in a peripheral direction) so as to open to the reference surface 21c of the ceramic body 20. As shown in FIG. 3, the outer-peripheral-plug disposition holes 25 are provided at a plurality of positions (for example, a plurality of locations at equal intervals in a peripheral direction) so as to open to the FR placement surface 26 of the ceramic body 20.

The base plate 30 is a conductive disk having good thermal conductivity (a disk having a diameter that is the same as or larger than the diameter of the ceramic body 20). A refrigerant flow path 32 in which refrigerant (for example, an electrically insulating liquid such as a fluorine-based inert liquid) circulates and the gas holes 34 that supply gas to the central plugs 50 and outer peripheral plugs are formed inside the base plate 30. Each gas hole 34 is provided so as to extend through the base plate 30 in the up-down direction, and has a large-diameter portion 34a at its upper portion. A plurality of gas holes 34 are provided at a plurality of positions in the base plate 30. The plurality of gas holes 34 correspond one-to-one to the central-plug disposition holes 24 and the outer-peripheral-plug disposition holes 25. Each large-diameter portion 34a of the plurality of gas holes 34, in plan view, encompasses the lower opening of the corresponding placement hole among the central-plug disposition holes 24 and the outer-peripheral-plug disposition holes 25. The refrigerant flow path 32 is formed in a one-stroke pattern from an inlet to an outlet over the entire surface of the base plate 30 in plan view. An example of a material of the base plate 30 is a metal or a composite material. An example of the metal is Mo or the like. An example of the composite material is a composite material of metal and ceramic, or the like. Examples of the composite material of metal and ceramic are a metal matrix composite material (MMC), a ceramic matrix composite material (CMC), and the like. Specific examples of such a composite material are a material containing Si, SiC, and Ti, a material in which Al and/or Si is impregnated in a SiC porous body, and the like. A material containing Si, SiC, and Ti is referred to as SiSiCTi, a material in which Al is impregnated in a SiC porous body is referred to as AlSiC, and a material in which Si is impregnated in a SiC porous body is referred to as SiSiC. As the material of the base plate 30, it is preferable to select a material having a coefficient of thermal expansion that is close to the coefficient of thermal expansion of a material of the ceramic body 20. The base plate 30 is used as an RF electrode. Specifically, an upper electrode (not shown) is disposed above a wafer placement surface 21, and when a high-frequency electric power is applied between parallel plate electrodes corresponding to the upper electrode and the baseplate 30, plasma is produced.

The metal joint layer 40 joins a lower surface of the ceramic body 20 and an upper surface of the baseplate 30. The metal joint layer 40 is formed by, for example, TCB (thermal compression bonding). TCB refers to a publicly known method of interposing a metal joint material between two members to be joined, and pressing and joining the two members while being heated at a temperature lower than or equal to a solidus temperature of the metal joint material. The metal joint layer 40 may be a solder layer or a brazing metal layer. The metal joint layer 40 has through holes 42. Each through hole 42 is provided at a position that is opposite to the large-diameter portion 34a of a corresponding one of the gas holes 34. Each through hole 42 is provided coaxially with the corresponding one of the large-diameter portions 34a, and the diameter of each through hole 42 is the same as the diameter of the corresponding one of the large-diameter portions 34a. “The same” in the present description encompasses in addition to exactly the same, substantially the same (for example, the case within the range of tolerance) (hereunder the same).

Each central plug 50 and each outer peripheral plug 55 are electrically insulating members through which a gas can pass internally. Each central plug 50 and each outer peripheral plug 55 are porous bodies and allow the gas to flow in the up-down direction. Each central plug 50 and each outer peripheral plug 55 are ceramic members such as alumina or aluminum nitride, and are, for example, formed of the same material as the ceramic body 20. The porosity of each central plug 50 and each outer peripheral plug 55 is preferably 30% or more, and the average pore diameter is preferably 20 μm or more. The porosity of each central plug 50 and each outer peripheral plug 55 may be 70% or less.

The central plug 50 is disposed in the central-plug disposition hole 24. The outer peripheral surface of the central plug 50 may be bonded to the inner peripheral surface of the central-plug disposition hole 24, or a male threaded portion provided on the outer peripheral surface of the central plug 50 may be screwed into a female threaded portion provided on the inner peripheral surface of the central-plug disposition hole 24. The central plug 50 has a shape whose cross-sectional area decreases from an upper surface 50a toward a lower surface 50b (for example, an inverted frustoconical shape), similar to the central-plug disposition hole 24. A plurality of central plugs 50 are provided in one-to-one correspondence with the plurality of central-plug disposition holes 24. The upper surface 50a of the central plug 50 is exposed at the upper opening of the central-plug disposition hole 24 and is disposed in the same plane as the reference surface 21c. In this specification, the term “same” includes not only a case of perfect identity but also a case of substantial identity (for example, within a tolerance range), and the same applies hereinafter. The central plug 50 and the central-plug disposition hole 24 are designed in advance so that, when the central plug 50 is inserted into the central-plug disposition hole 24 and the outer peripheral surface of the central plug 50 is matched with the inner peripheral surface of the central-plug disposition hole 24, the height of the upper surface 50a of the central plug 50 matches the height of the reference surface 21c of the ceramic body 20. Therefore, the upper surface 50a of the central plug 50 and the reference surface 21c of the ceramic body 20 can be easily made coplanar. The height of the lower surface 50b of the central plug 50 may be the same as the height of the lower surface of the ceramic body 20, or may be higher or lower than that.

The outer peripheral plug 55 is disposed in the outer-peripheral-plug disposition hole 25. The outer peripheral surface of the outer peripheral plug 55 may be bonded to the inner peripheral surface of the outer-peripheral-plug disposition hole 25, or a male threaded portion provided on the outer peripheral surface of the outer peripheral plug 55 may be screwed into a female threaded portion provided on the inner peripheral surface of the outer-peripheral-plug disposition hole 25. The outer peripheral plug 55 has a shape whose cross-sectional area decreases from an upper surface 55a toward a lower surface 55b (for example, an inverted frustoconical shape), similar to the outer-peripheral-plug disposition hole 25. A plurality of outer peripheral plugs 55 are provided in one-to-one correspondence with the plurality of outer-peripheral-plug disposition holes 25. The length of the outer peripheral plug 55 in the up-down direction is designed to be greater than the length of the outer-peripheral-plug disposition hole 25 in the up-down direction, and an upper end portion of the outer peripheral plug 55 protrudes upward beyond the FR placement surface 26 and the upper opening of the outer-peripheral-plug disposition hole 25. Therefore, the upper surface 55a of the outer peripheral plug 55 is disposed at a height higher than the FR placement surface 26. The height of the lower surface 55b of the outer peripheral plug 55 may be the same as the height of the lower surface of the ceramic body 20, or may be higher or lower than that.

The focus ring 60 is a conductive member placed on the FR placement surface 26 of the ceramic body 20. Examples of the material of the focus ring 60 include metal silicon. When the plasma process is plasma etching, the material of the focus ring 60 is appropriately selected according to the type of film on the wafer W to be etched. An annular stepped surface 62c having an L-shaped cross section along an inner circumference of the focus ring 60 is formed on the upper portion of the focus ring 60. Accordingly, the annular stepped surface 62c is at a height lower than the upper surface 62a of the focus ring 60. The annular stepped surface 62c is disposed in the same plane as the wafer placement surface 21. The outer diameter of the annular stepped surface 62c is formed slightly larger than the outer diameter of the wafer W and the outer diameter of the wafer placement surface 21 so as not to interfere with the wafer W. The outer diameter of the focus ring 60 is larger than the outer diameter of the ceramic body 20. Therefore, the focus ring 60 is placed on the FR placement surface 26 in a state of overhanging to the outside of the wafer placement table 10. The focus ring 60 is merely placed on the FR placement surface 26 without being bonded the FR placement surface 26.

The focus ring 60 has a lower surface 62b, and the lower surface 62b has a recessed portion 63 for pooling gas at a position opposed to the outer peripheral plug 55. As shown in FIG. 4, the recessed portion 63 is formed in a circular shape in plan view, and a space inside the recessed portion 63 is cylindrical. The bottom surface 63a of the recessed portion 63 is at a position higher than the FR placement surface 26 and the lower surface 62b, and at a position lower than the wafer placement surface 21. The bottom surface 63a is at a position lower than the reference surface 21c. In plan view, the recessed portion 63 is disposed outside the annular stepped surface 62c. That is, in plan view, the recessed portion 63 is disposed at a position not overlapping the annular stepped surface 62c. The upper end portion of the outer peripheral plug 55 protrudes upward beyond the FR placement surface 26 and is inserted into the recessed portion 63. Accordingly, the upper surface 55a of the outer peripheral plug 55 is disposed within the recessed portion 63 and is located at a position higher than the lower surface 62b of the focus ring 60. The bottom surface 63a of the recessed portion 63 is located at a position higher than the upper surface 55a of the outer peripheral plug 55. Although the outer peripheral plug 55 does not contact the bottom surface 63a and a side surface of the recessed portion 63, at least a part of the outer peripheral plug 55 may contact the bottom surface 63a and/or the side surface. In this embodiment, a plurality of recessed portions 63 are provided, in one-to-one correspondence with the plurality of outer peripheral plugs 55, as shown in FIG. 4. Therefore, the upper surface 55a of each of the plurality of outer peripheral plugs 55 is disposed inside a corresponding one of the plurality of recessed portions 63. The depth (height) of the recessed portion 63 may be 1 mm or less, and may be 0.5 mm or less. The depth of the recessed portion 63 may be 0.5 mm or more. The distance between the bottom surface 63a of the recessed portion 63 and the upper surface 55a of the outer peripheral plug 55 in the up-down direction may be 0.2 mm or less. In this embodiment, no recessed portion is formed, at least in a region of the FR placement surface 26 around the upper surface 55a of the outer peripheral plug 55. Therefore, there is no space at a position lower than the FR mounting surface 26 for pooling the gas supplied through the outer peripheral plug 55.

Next, an example of the use of the wafer placement table 10 thus configured will now be described. The wafer W is first placed on the wafer placement surface 21 with the wafer placement table 10 installed in a chamber not illustrated. The pressure of the chamber is decompressed by a vacuum pump and is adjusted such that a predetermined degree of vacuum is achieved. A direct voltage is applied to the first electrode 22 of the ceramic body 20 to generate electrostatic attraction force, and the wafer W is attracted and secured to the wafer placement surface 21. A direct voltage is also applied to the second electrode 23 to generate electrostatic attraction force, and the focus ring 60 is attracted and secured to the FR placement surface 26. Subsequently, a reactive gas atmosphere at a predetermined pressure (for example, several tens of Pa to several hundreds of Pa) is created in the chamber. In this state, a high-frequency voltage is applied between an upper electrode, not illustrated, on a ceiling portion in the chamber and the base plate 30 of the wafer placement table 10, and plasma is generated. The surface of the wafer W is processed by the generated plasma. The refrigerant circulates through the refrigerant flow path 32 of the base plate 30. Backside gas is introduced into the gas holes 34 from a gas tank not illustrated. Heat-conduction gas (such as helium) is used as the backside gas. The backside gas passes through the gas holes 34, the through holes 42, and the central plug 50, is supplied to a space between the back surface of the wafer W and the reference surface 21c, and is sealed. The presence of this backside gas enables efficient heat conduction between the wafer W and the ceramic body 20. The backside gas also passes through the gas holes 34, the through holes 42, and the outer peripheral plug 55, and is supplied to and sealed in the space within the recessed portion 63. The presence of this backside gas enables efficient heat conduction between the focus ring 60 and the ceramic body 20.

Moreover, because the recessed portion 63 for storing the backside gas is located inside the focus ring 60 having conductive, that is, at a position above the lower surface 62b, the potential of the space inside the recessed portion 63 during use of the wafer placement table 10 becomes the same as or close to the potential of the focus ring 60, thereby making it possible to reduce the potential difference within the space. Accordingly, in the space within the recessed portion 63, that is, in the space for pooling gas between the focus ring 60 and the ceramic body 20, discharge can be suppressed. For example, as a comparative example, consider a configuration in which the focus ring 60 has no recessed portion 63, a recessed portion is instead provided in the FR placement surface 26 of the ceramic body 20, and the upper surface of the outer peripheral plug 55 is made to coincide with the bottom surface of that recessed portion (a surface lower than the FR placement surface 26), and backside gas is pooled in this recessed portion. Because the space inside the recessed portion of this comparative example is located below the lower surface 62b of the focus ring 60 having conductive, the potential difference in the space tends to be larger than in the space inside the recessed portion 63 of the present embodiment, and discharge is more likely to occur. In contrast, in the recessed portion 63 of the present embodiment, the potential difference within the space can be reduced compared with the recessed portion of the comparative example, and discharge can be suppressed. In addition, because the FR placement surface 26 is located lower than the wafer placement surface 21, the distance (distance between conductors) between the focus ring 60 and the base plate 30 in the up-down direction is smaller than the distance between the wafer W and the base plate 30 in the up-down direction. Therefore, compared with the space between the lower surface of the wafer W and the upper surface 50a of the central plug 50, the space inside the recessed portion 63 has a smaller distance between conductors even under the same applied voltage, so the electric field strength tends to be higher. Thus, suppressing discharge in the recessed portion 63 is important.

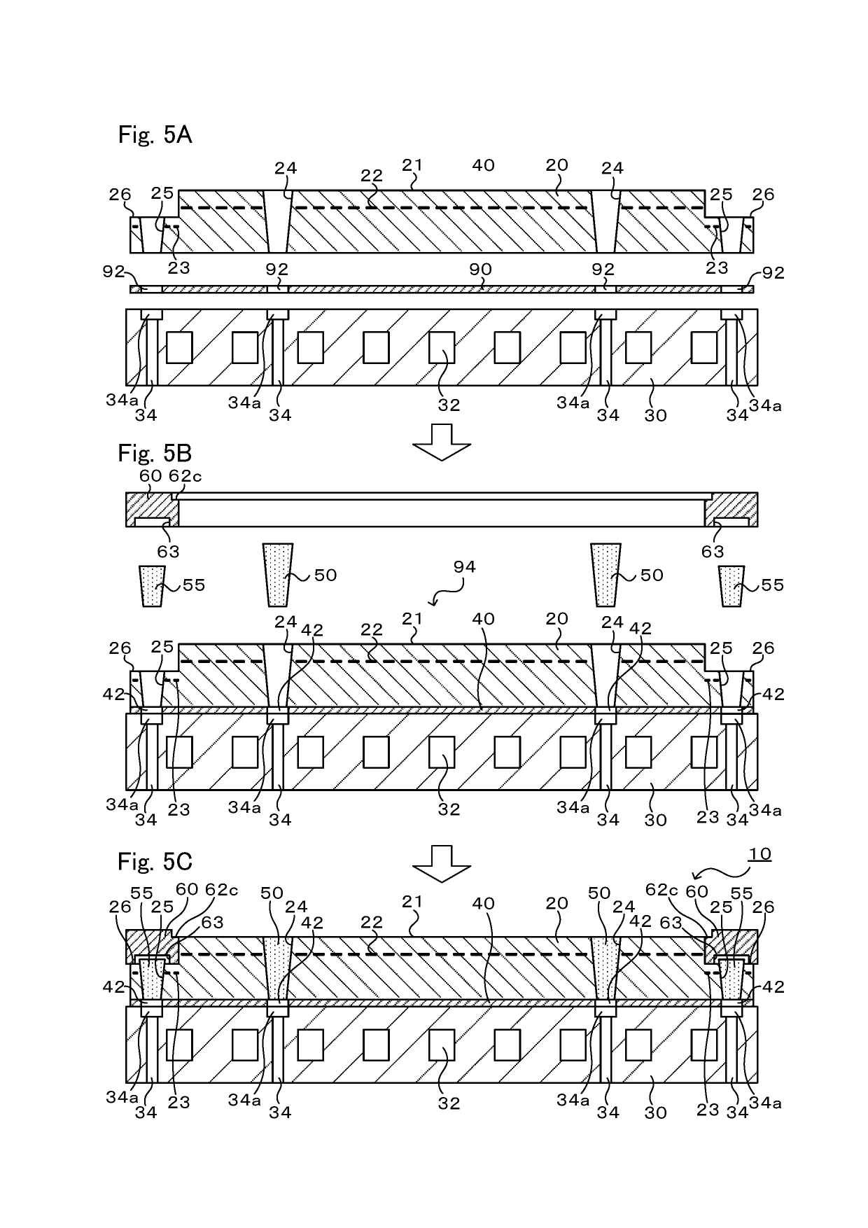

Next, an example of manufacturing the wafer placement table 10 is described based on FIGS. 5A to 5C. FIGS. 5A to 5C show the steps of manufacturing the wafer placement table 10. First, a ceramic body 20, a baseplate 30, and a metal joint material 90 are prepared (FIG. 5A). The ceramic body 20 has a first electrode 22 and a second electrode 23 built therein, and has central plug disposition holes 24 and peripheral plug disposition holes 25. The baseplate 30 has a refrigerant flow path 32 and gas holes 34. Each gas hole 34 has a large-diameter portion 34a at its upper portion. The metal joint material 90 has through holes 92 at positions that are opposite to the large-diameter portions 34a of the respective gas holes 34.

Next, the metal joint material 90 is interposed between a lower surface of the ceramic body 20 and an upper surface of the baseplate 30 to form a layered body. At this time, the central plug disposition holes 24 and the peripheral plug disposition holes 25 of the ceramic body 20, the through holes 92 of the metal joint material 90, and the gas holes 34 of the baseplate 30 are placed upon each other so as to be coaxial with each other. Then, the layered body is pressed and joined at a temperature less than or equal to a solidus temperature of the metal joint material 90 (for example, greater than or equal to a temperature obtained by subtracting 20°C from the solidus temperature and less than or equal to the solidus temperature), after which the temperature is returned to room temperature (TCB). Therefore, the metal joint material 90 becomes a metal joint layer 40 and the through holes 92 become through holes 42, as a result of which a joint body 94 obtained by joining the ceramic body 20 and the baseplate 30 by the metal joint layer 40 can be obtained (FIG. 5B). Note that, as the metal joint material 90, an Al-Mg-based joint material or an Al-Si-Mg-based joint material can be used. The metal joint material 90 is preferably one having a thickness of about 100 μm.

Next, the central plugs 50 are mounted in the central-plug disposition holes 24 of the bonded body 94, and the outer peripheral plugs 55 are mounted in the outer-peripheral-plug disposition holes 25 (FIG. 5B). The installation of the central plug 50 may, for example, be performed by preparing a central plug 50 previously formed by firing, applying an adhesive to the central plug disposition hole 24, inserting the central plug 50 into the central plug disposition hole 24 from above, and adhesively fixing the outer circumferential surface of the central plug 50 to the inner circumferential surface of the central plug disposition hole 24. Alternatively, the central plug 50 may be mounted by forming a male-threaded portion on the outer circumferential surface of the central plug 50 and a female-threaded portion on the inner circumferential surface of the central plug disposition hole 24, inserting the central plug 50 by screwing it into the central plug disposition hole 24, and thereby bringing the male-threaded portion of the central plug 50 and the female-threaded portion of the central plug disposition hole 24 into threaded engagement. The outer peripheral plugs 55 can be mounted in the same manner.

Further, for example, a focus ring 60 in which the annular stepped surface 62c and the recessed portion 63 have been formed in advance by machining is prepared (FIG. 5B). After the central plugs 50 and the outer peripheral plugs 55 are mounted to the bonded body 94, the focus ring 60 is placed on the FR placement surface 26. At this time, the focus ring 60 is placed such that the upper end of the outer peripheral plug 55 is inserted into the recessed portion 63. Thus, the wafer placement table 10 is obtained (FIG. 5C).

Here, the correspondence relationship between the elements according to the present embodiment and the elements according to the present invention will be clarified. The ceramic body 20 according to the present embodiment corresponds to the ceramic body according to the present invention; the first electrode 22 and the second electrode 23 correspond to the electrode; the focus ring 60 corresponds to the focus ring; the outer-peripheral-plug disposition hole 25 corresponds to the plug disposition hole; the outer peripheral plug 55 corresponds to the plug; the recessed portion 63 corresponds to the recessed portion; and the upper surface 55a corresponds to the upper surface of the plug.

In the wafer placement table 10 described in detail above, the outer peripheral plug 55 that allows gas to pass through interior thereof is provided in the outer peripheral plug disposition hole 25 that is located below the focus ring 60 having conductive and penetrates the ceramic body 20. The focus ring 60 has the lower surface 62b, and the lower surface 62b has the recessed portion 63 for pooling gas at the position opposed to the outer peripheral plug 55. The upper surface 55a of the outer peripheral plug 55 is disposed within the recessed portion 63 and is located at the position higher than the lower surface 62b of the focus ring 60. In this way, because the recessed portion 63 for pooling gas supplied via the outer peripheral plug 55 is located on the inside of the focus ring 60 having conductive, the potential of the space within the recessed portion 63 during use of the wafer placement table 10 becomes the same as, or close to, a potential of the focus ring 60, thereby reducing the potential difference within the space. Accordingly, discharge can be suppressed in the space within the recessed portion 63, that is, in the gas-pooling space between the focus ring 60 and the ceramic body 20.

Further, the bottom surface 63a of the recessed portion 63 is at the position lower than the wafer placement surface 21. In this manner, the height from an upper surface 62a of the focus ring 60 to the bottom surface 63a of the recessed portion 63 becomes sufficiently large. Accordingly, when the upper-surface side of the focus ring 60 wears due to use of the wafer placement table 10, exposure of the recessed portion 63 on the side of the upper surface 62a (that is, communication of the space within the recessed portion 63 with the space above the upper surface 62a) can be suppressed.

It should be noted that the present invention is not limited to the present embodiment described above in any way, and it goes without saying that the present invention can be implemented in various modes as long as they fall within the technical scope of the present invention.

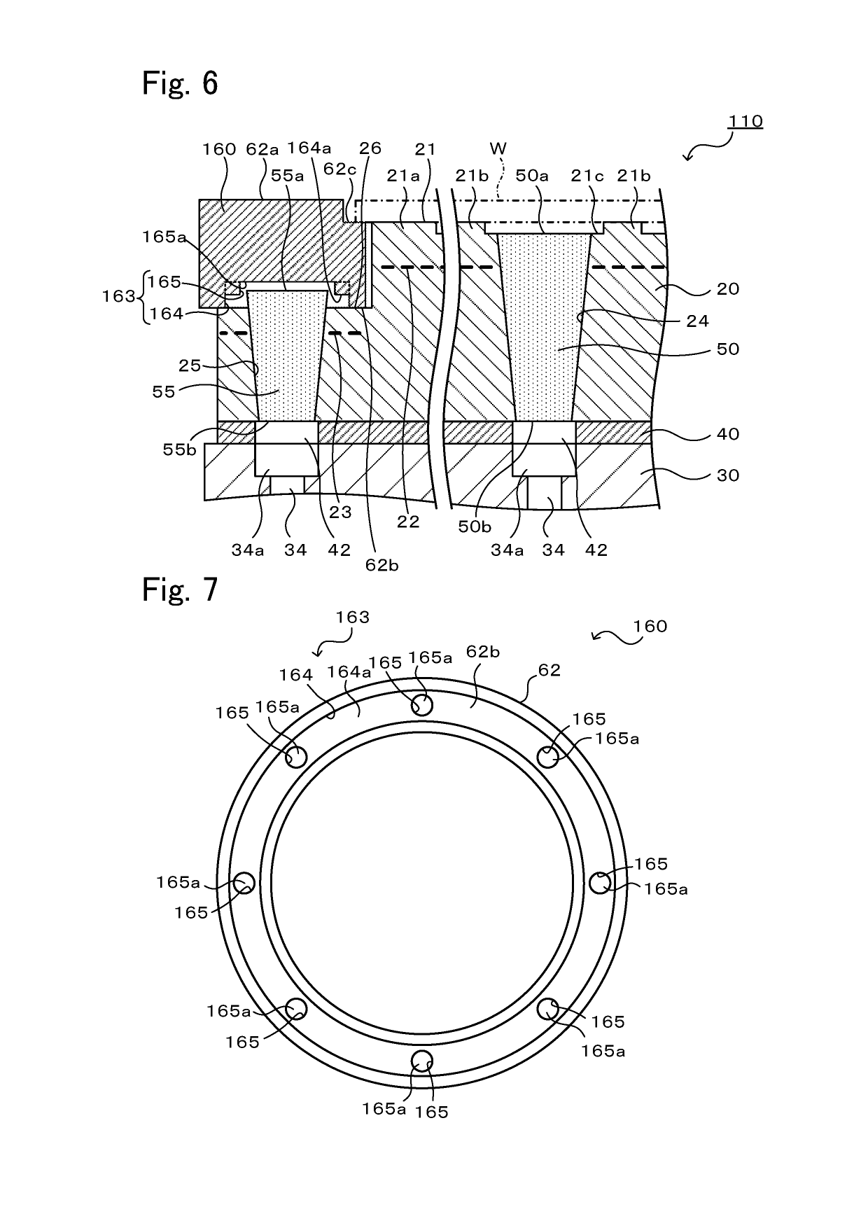

For example, in place of the focus ring 60 of the embodiment described above, the mode of a focus ring 160 shown in FIGS. 6 and 7 may be adopted. FIG. 6 is an enlarged partial longitudinal cross-sectional view of a wafer placement table 110 provided with the focus ring 160. FIG. 7 is a plan view of the focus ring 160 as seen from below. As shown in FIGS. 6 and 7, a recessed portion 163 of the focus ring 160 has an annular groove 164 and a hole portions 165. The annular groove 164 is provided at an outer peripheral portion of the wafer placement surface 21. The annular groove 164 is provided so as to surround the wafer placement surface 21 in plan view. The hole portion 165 is narrower in width than the annular groove 164. The hole portion 165 is a hole formed in a bottom surface 164a of the annular groove 164, and a bottom surface 165a of the hole portion 165 is at a position higher than the bottom surface 164a of the annular groove 164. The recessed portion 163 has one or more hole portions 165, and in FIGS. 6 and 7 has a plurality of hole portions 165 corresponding to a plurality of outer peripheral plugs 55. The plurality of hole portions 165 are each formed circular in plan view as shown in FIG. 7, and the inner space of each hole portion 165 is cylindrical. The plurality of hole portions 165 are in one-to-one correspondence with the plurality of outer peripheral plugs 55, and the upper surface 55a of each of the plurality of outer peripheral plugs 55 is disposed within the corresponding one of the plurality of hole portions 165. That is, each of the plurality of outer peripheral plugs 55 is inserted into the annular groove 164 within the recessed portion 163, and further, the upper end of each of the plurality of outer peripheral plugs 55 reaches into the corresponding hole portion 165. Accordingly, the bottom surface 164a of the annular groove 164 is at a position lower than the upper surface 55a of the outer peripheral plug 55.

In this focus ring 160, as compared with a case in which, as in the embodiment described above, a plurality of recessed portions 63 are provided independently for the respective plurality of outer peripheral plugs 55 and are scattered, the provision of the annular groove 164 in the recessed portion 163 makes it possible to supply backside gas overall between the focus ring 160 and the ceramic body 20. Further, the contact area between the focus ring 160 and the backside gas can be increased. Accordingly, heat conduction between the focus ring 160 and the ceramic body 20 via the gas within the recessed portion 163 can be improved.

Further, in this focus ring 160, the recessed portion 163 includes the annular groove 164 and the hole portion 165 having the width narrower than that of the annular groove 164 and having the bottom surface 165a located higher than the bottom surface 164a of the annular groove 164. The upper surface 55a of each of the plurality of outer peripheral plugs 55 is disposed within the hole portion 165. Here, for example, where the recessed portion 163 has only the annular groove 164 to the depth reaching the bottom surface 165a of the hole portion 165 (see the broken line in FIG. 6), widening the annular groove 164 can further improve heat conduction between the focus ring 160 and the ceramic body 20 through the backside gas within the recessed portion 163, but it tends to increase the space volume within the recessed portion 163 and make discharge within the recessed portion 163 more likely. In contrast, by providing the recessed portion 163 with both the annular groove 164 having the wide width and having the bottom surface 164a located at the low position, and the hole portion 165 having the narrow width and having the bottom surface 165a located at the high position, the depth of the annular groove 164 can be made shallower while allowing the outer peripheral plug 55 to be disposed in the recessed portion 163, thereby reducing the space volume within the recessed portion 163. Thus, discharge within the recessed portion 163 can be suppressed while further improving heat conduction between the focus ring 160 and the ceramic body 20.

In the focus ring 160 shown in FIGS. 6 and 7, the plurality of hole portions 165 of the recessed portion 163 are in one-to-one correspondence with the plurality of outer peripheral plugs 55, and the upper surface 55a of each of the plurality of outer peripheral plugs 55 is disposed within the corresponding one of the plurality of hole portions 165, however, the present invention is not limited thereto. For example, it suffices that the number of the hole portions 165 of the recessed portion 163 is one or more. Specifically, the number of the plurality of hole portions 165 of the recessed portion 163 may be smaller than the number of the outer peripheral plugs 55, and, for example, two outer peripheral plugs 55 may be inserted into one hole portion 165. In this case, the hole portion 165 may have an arcuate shape in plan view. The recessed portion 163 may have a single hole portion 165, and this hole portion 165 may be an annular groove. That is, the recessed portion 163 may have the annular groove 164 having larger width and having the bottom surface 164a located at the low position, and an annular groove (the hole portion 165) having smaller width and having the bottom surface 165a located at the high position. Alternatively, the recessed portion 163 may have only the annular groove 164 without having the hole portion 165. However, as described above, since the outer peripheral plug 55 can be disposed within the recessed portion 163 while reducing the space volume within the recessed portion 163, it is preferable that the recessed portion 163 have both the annular groove 164 and the hole portion 165.

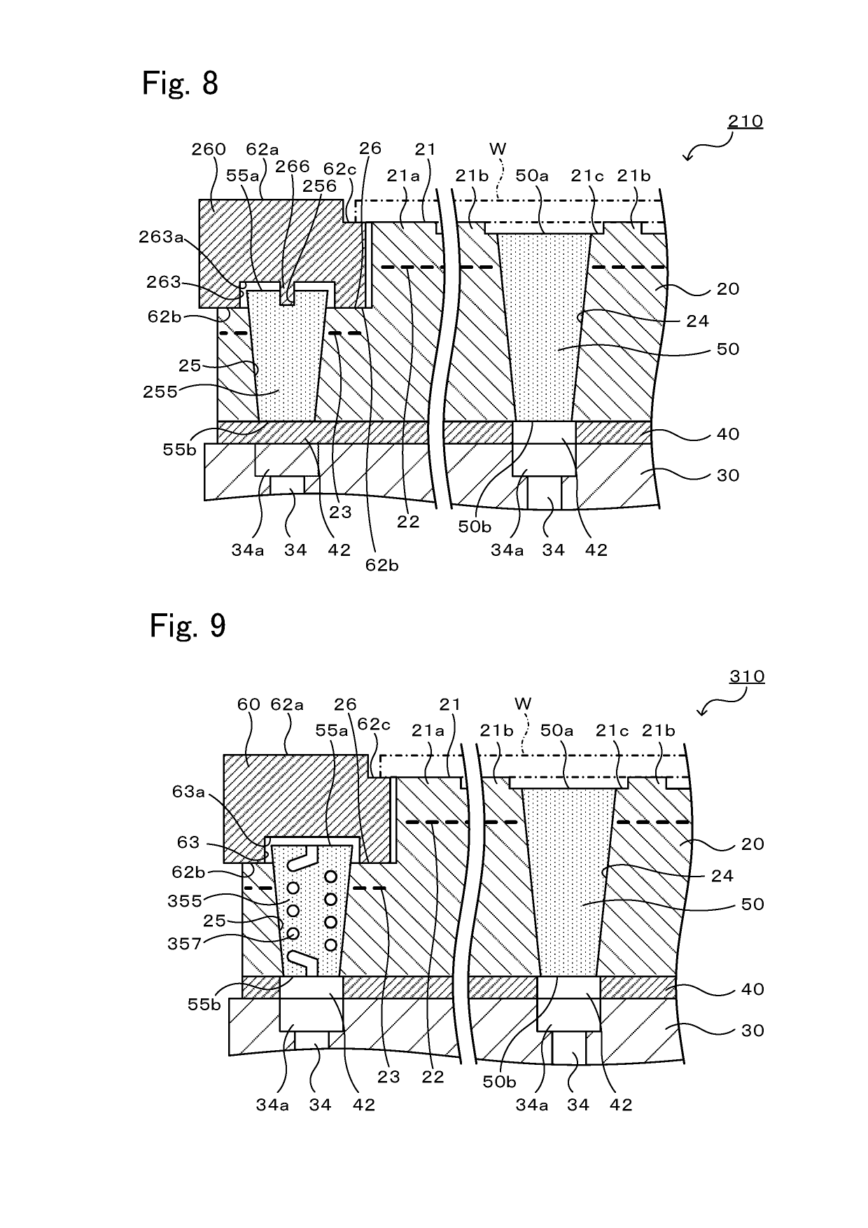

In place of the focus ring 60 of the embodiment described above, the mode of a focus ring 260 shown in FIG. 8 may be adopted. FIG. 8 is an enlarged partial longitudinal cross-sectional view of a wafer placement table 210 provided with the focus ring 260. As shown in FIG. 8, the focus ring 260 has, within a recessed portion 263, a protruding portion 266 that protrudes downward from a bottom surface 263a. The protruding portion 266 is formed, for example, in a cylindrical shape. The wafer placement table 210 includes, in place of the outer peripheral plug 55, an outer peripheral plug 255. The upper surface 55a of the outer peripheral plug 255 is disposed within the recessed portion 263 and is at a position higher than the lower surface 62b of the focus ring 260. The outer peripheral plug 255 has a hole 256 in its upper surface 55a. The hole 256 opens at the upper surface 55a. The protruding portion 266 of the focus ring 260 is inserted into the hole 256 of the outer peripheral plug 255. In this wafer placement table 210, a lower end of the protruding portion 266, which is part of the focus ring 260 having conductive, exists at a position lower than the upper surface 55a of the outer peripheral plug 255 and inside the outer peripheral plug 255. Therefore, the potential of the space around the protruding portion 266 during use of the wafer placement table 210, that is, the potential of the space around the upper surface 55a of the outer peripheral plug 255, becomes the same as or close to that of the focus ring 260. Accordingly, a potential difference is less likely to arise in the space around the upper surface 55a of the outer peripheral plug 255, and discharge within the recessed portion 263 can be further suppressed.

In the focus ring 260 shown in FIG. 8, it is preferable that the lower end of the protruding portion 266 is at the same position as, or at a position higher than, the lower surface 62b of the focus ring 260. The protruding portion 266 may or may not be in contact with the outer peripheral plug 255 within the hole 256 of the outer peripheral plug 255. When the protruding portion 266 contacts the outer peripheral plug 255, the lower end of the protruding portion 266 may contact the outer peripheral plug 255, or a side surface of the protruding portion 266 may contact the outer peripheral plug 255. Also in the focus ring 160 shown in FIGS. 6 and 7, a protruding portion that protrudes downward from the bottom surface 165a of the hole portion 165 and is inserted into the outer peripheral plug 55 may be provided.

In the embodiment described above, the outer peripheral plug 55 is a porous body, but the present invention is not limited thereto; it suffices that the interior of the outer peripheral plug 55 allows gas to pass. For example, the outer peripheral plug 55 may be a dense body having an internal gas flow path through which gas can pass. A wafer placement table 310 shown in FIG. 9 includes, in place of the outer peripheral plug 55, an outer peripheral plug 355. The outer peripheral plug 355 is an electrically insulating dense body and has a gas internal flow path 357. The gas internal flow path 357 is a flow path that allows the flow of gas between the upper surface 55a and the lower surface 55b of the outer peripheral plug 355. The gas internal flow path 357 opens at each of the upper surface 55a and the lower surface 55b. The gas internal flow path 357 is a passage penetrating from the upper side to the lower side of the outer peripheral plug 355 while meandering, and, more specifically, is configured as a helical passage. As another example of a meandering penetrating passage, a zigzag passage may be employed. The gas internal flow path 357 may be a straight through hole extending in the up-down direction. A diameter of the flow-path cross-section of the gas internal flow path 357 is preferably 0.1 mm or more and 1 mm or less. One outer peripheral plug 355 may have a plurality of gas internal flow paths 357. A porosity of the dense portion of the outer peripheral plug 355 is preferably less than 0.1%. As the outer peripheral plug 355, similarly to the outer peripheral plug 55, for example, a ceramic such as alumina or aluminum nitride can be used. The outer peripheral plug 355 may have the hole 256 for insertion of the protruding portion 266 shown in FIG. 8; in that case, the hole 256 and the opening of the gas internal flow path 357 may be provided at different locations on the upper surface 55a. The central plug 50 may likewise be a dense body having a gas internal flow path.

In the embodiment described above, the upper surfaces of the seal band 21a and the circular small projections 21b constitute the wafer placement surface 21; however, the ceramic body 20 may not necessarily have the seal band 21a and the circular small projections 21b. In that case, the wafer placement surface 21 may be a flat surface (the reference surface 21c).

In the embodiment described above, the ceramic body 20 has the first electrode 22 and the second electrode 23 built therein; however, the ceramic body 20 may have the first electrode 22 built therein without the second electrode 23 being built therein.

In the embodiment described above, the first electrode 22 and the second electrode 23 built in the ceramic body 20 were electrostatic electrodes; however, the electrodes built in the ceramic body 20 are not particularly limited thereto. For example, the ceramic body 20 may have a heater electrode (resistance heating element) built therein or may have an RF electrode built therein, instead of or in addition to the first electrode 22.

In the embodiment described above, the ceramic body 20 and the base plate 30 are joined by a metal joint layer 40, but a resin adhesive layer may be used instead of the metal joint layer 40.

In the embodiment described above, the ceramic body 20 is an integrally formed member, but it may instead be constituted by a plurality of members. For example, the ceramic body 20 may be configured as separate members: a portion having the wafer placement surface 21 with the first electrode 22 built in, and a portion having the focus ring placement surface 26 with the second electrode 23 built in.

In the embodiment described above, the plurality of gas holes 34 formed in the base plate 30 are in one-to-one correspondence with the central-plug disposition holes 24 and the outer-peripheral-plug disposition holes 25, and the plurality of gas holes 34 constitute mutually independent flow paths; however, the present invention is not limited thereto. For example, the base plate 30 may have a gas introduction portion that introduces gas from a lower surface of the base plate 30, and a distribution portion that branches from the gas introduction portion into a plurality of passages to serve as gas flow paths to each of the central-plug disposition holes 24 and the outer-peripheral-plug disposition holes 25.

In the embodiment described above, the wafer placement table 10 is provided with the ceramic body 20, the base plate 30, the metal joint layer 40, the central plug 50, the outer peripheral plug 55, and the focus ring 60; however, as long as the wafer placement table is provided with the ceramic body 20, the outer peripheral plug 55, and the focus ring 60, the other configuration is not particularly limited. For example, the metal joint layer 40 or the base plate 30 may not be provided.

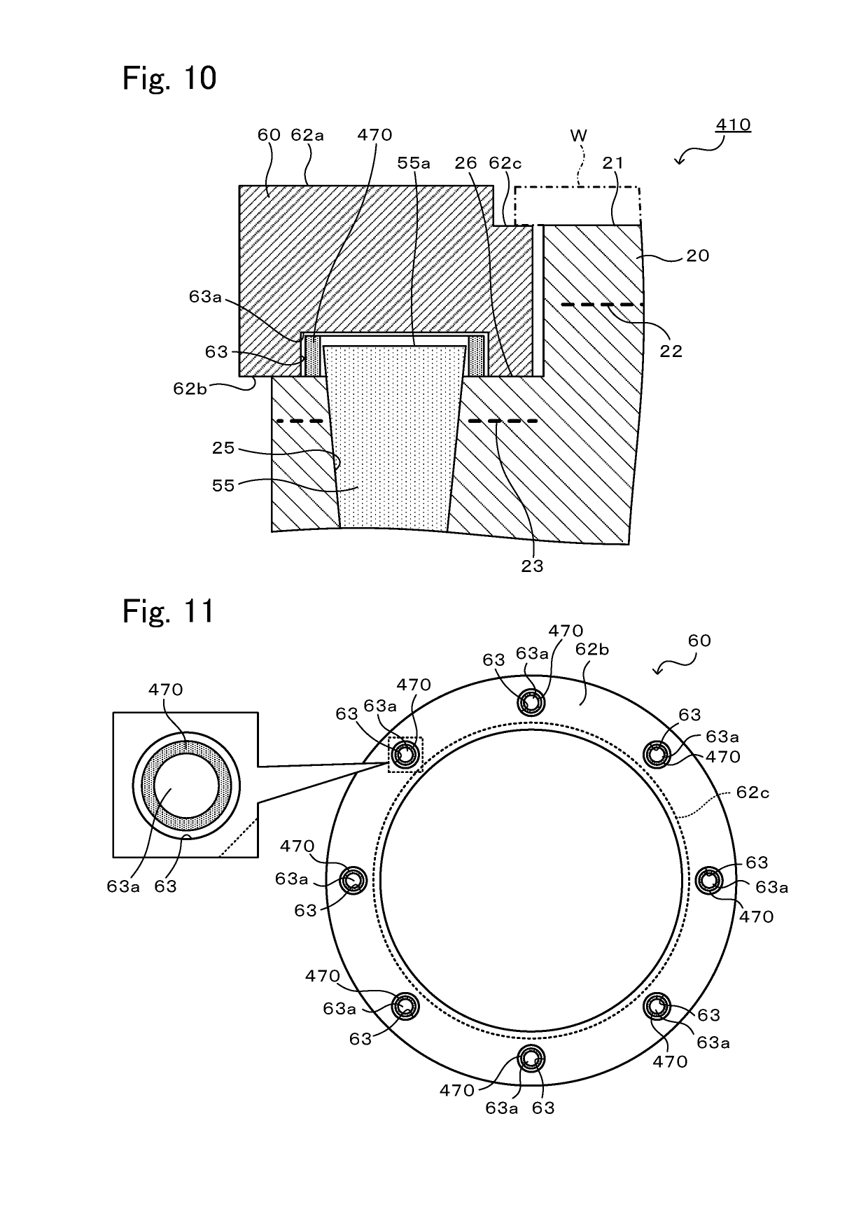

In the embodiment described above, an auxiliary member may be disposed between the focus ring 60 and the outer peripheral plug 55. FIG. 10 is a partially enlarged vertical cross-sectional view of a wafer placement table 410 according to a modification. FIG. 11 is a plan view of the focus ring 60 and an auxiliary member 470 of the wafer placement table 410 as seen from below. In FIG. 11, hatching is applied to the auxiliary member 470 for clarity of placement. The wafer placement table 410 further includes the auxiliary member 470 disposed between the focus ring 60 and the outer peripheral plug 55, in addition to the components of the wafer placement table 10 described above. The auxiliary member 470 is disposed within the recessed portion 63 of the focus ring 60. More specifically, as shown in FIG. 10, the auxiliary member 470 is disposed between the side surface of the portion of the outer peripheral plug 55 located within the recessed portion 63 and the side surface of the recessed portion 63. The auxiliary member 470 has a ring (cylindrical) shape, and the outer peripheral plug 55 is disposed inside the auxiliary member 470. Thus, the auxiliary member 470 surrounds the side surface of the portion of the outer peripheral plug 55 located within the recessed portion 63. As shown in FIG. 11, the plurality of recessed portions 63 and the plurality of auxiliary members 470 are each provided in one-to-one correspondence with the plurality of outer peripheral plugs 55. In this way, the presence of the auxiliary member 470 within the recessed portion 63 allows the auxiliary member 470 to fill the gap between the focus ring 60 and the outer peripheral plug 55 within the recessed portion 63. As a result, the space volume between the side surface of the outer peripheral plug 55 and the side surface of the recessed portion 63 within the recessed portion 63 can be reduced. Therefore, discharge within the recessed portion 63 can be further suppressed.

It is preferable that the auxiliary member 470 is a member having conductive. The auxiliary member 470 may be made of the same material as the focus ring 60. It is preferable that the auxiliary member 470 is electrically continuous with the focus ring 60. For example, although in FIG. 10 the auxiliary member 470 is not in contact with the focus ring 60, it is preferable that the auxiliary member 470 is in contact with the focus ring 60 so that they are electrically continuous. If the auxiliary member 470 is conductive and electrically continuous with the focus ring 60, the auxiliary member 470 will be at the same potential as the focus ring 60, whereby the potential difference in the space within the recessed portion 63 can be further reduced and discharge within the recessed portion 63 can be further suppressed. The same applies to the auxiliary members 570 and 670 described later.

When, for example, a plurality of wafer placement tables 410 are manufactured, variations in machining during manufacture of the focus ring 60 and the outer peripheral plug 55 may cause variations, among the wafer placement tables 410, in the size of the space between the recessed portion 63 and the outer peripheral plug 55 and in the positional relationship between the inner peripheral surface of the recessed portion 63 and the outer peripheral plug 55. Even in such a case, during the step of placing the focus ring 60 on the focus ring placement surface 26 (FIG. 5B), by disposing within the recessed portion 63 an auxiliary member 470 of an appropriate size that accounts for machining variations, the space volume between the outer peripheral plug 55 and the recessed portion 63 within the recessed portion 63 can be reduced, thereby reducing the influence of machining variations. In addition, due to thermal expansion of the focus ring 60 during use of the wafer placement table 410, the size of the space between the recessed portion 63 and the outer peripheral plug 55 and the positional relationship between the inner peripheral surface of the recessed portion 63 and the outer peripheral plug 55 may change. For example, since the diameter of the focus ring 60 is often larger than its thickness, thermal expansion of the focus ring 60 tends to particularly increase the space between the side surface of the outer peripheral plug 55 and the side surface of the recessed portion 63, which may make discharge likely to occur in that space. Even in such a case, the presence within the recessed portion 63 of the auxiliary member 470, which is a member separate from the focus ring 60, makes it possible to reduce the space volume between the side surface of the outer peripheral plug 55 and the side surface of the recessed portion 63, thereby suppressing discharge in that space. As can also be seen from FIGS. 10 and 11, the auxiliary member 470 is a member having a smaller diameter than the focus ring 60 and undergoes a smaller dimensional change due to thermal expansion; therefore, the presence of the auxiliary member 470 can effectively suppress the influence on discharge due to thermal expansion of the focus ring 60. These effects similarly apply to the auxiliary members 570 and 670 described later.

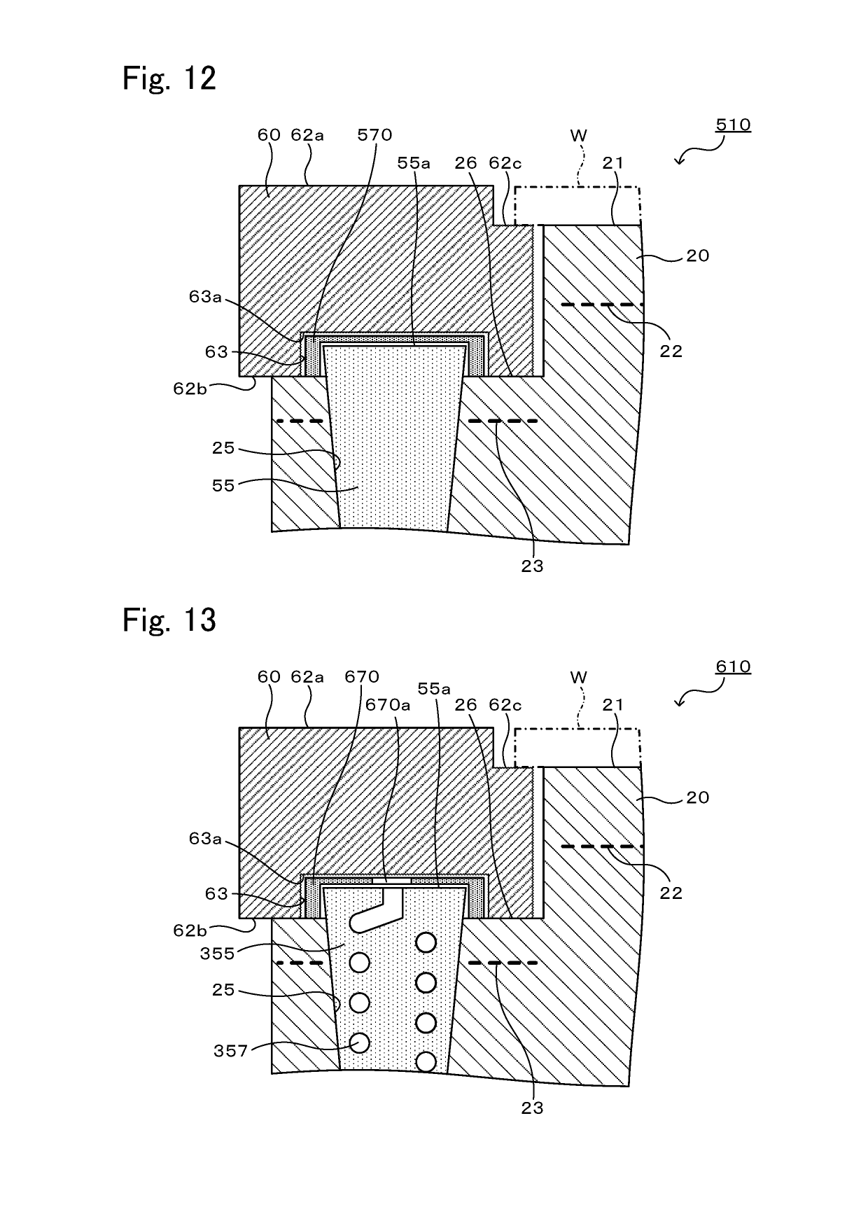

In place of the auxiliary member 470 of FIG. 10, an auxiliary member 570 shown in FIG. 12 may be adopted. FIG. 12 is a partially enlarged vertical cross-sectional view of a wafer placement table 510 according to a modification. The wafer placement table 510 further includes the auxiliary member 570 disposed between the focus ring 60 and the outer peripheral plug 55, in addition to the components of the wafer placement table 10 described above. The auxiliary member 570 is disposed between the side surface of the outer peripheral plug 55 and the side surface of the recessed portion 63, as with the auxiliary member 470, and is further present between the upper surface 55a of the outer peripheral plug 55 and the bottom surface 63a of the recessed portion 63. The auxiliary member 570 has a shape that closes the opening at the upper end of the ring of the auxiliary member 470, that is, a bottomed cylindrical (cap-like) shape. Thus, the auxiliary member 570 surrounds the upper surface 55a of the outer peripheral plug 55 and the periphery of the side surface of the portion of the outer peripheral plug 55 located within the recessed portion 63. In other words, the auxiliary member 570 covers the upper-end portion of the outer peripheral plug 55 that is located within the recessed portion 63 as a whole. This auxiliary member 570 not only reduces, like the auxiliary member 470, the space volume between the side surface of the outer peripheral plug 55 and the side surface of the recessed portion 63 within the recessed portion 63, but also reduces the space volume between the upper surface 55a of the outer peripheral plug 55 and the bottom surface 63a of the recessed portion 63. Accordingly, discharge within the recessed portion 63 can be further suppressed.

The auxiliary member 570 may allow gas to pass through an interior thereof. FIG. 13 is a partially enlarged vertical cross-sectional view of a wafer placement table 610 according to a modification. The wafer placement table 610 further includes an auxiliary member 670 disposed between the focus ring 60 and the outer peripheral plug 355, in addition to the components of the wafer placement table 310 described above. Except that the auxiliary member 670 has a gas passage hole 670a at its upper portion so that gas can pass through an interior of the auxiliary member 670, the auxiliary member 670 is the same as the auxiliary member 570. The gas passage hole 670a is provided at a position facing the opening of the gas internal flow path 357 within the recessed portion 63, more specifically, at a position directly above the opening of the gas internal flow path 357 at the upper surface 55a of the outer peripheral plug 355. By providing the auxiliary member 670 with the gas passage hole 670a in this way, gas that has passed through the gas internal flow path 357 of the outer peripheral plug 355 more readily distributed in the space within the recessed portion 63. As a result, during use of the wafer placement table 610, the backside gas can be accumulated in the recessed portion 63 in a short time. The position of the gas passage hole 670a is not limited to a position facing the opening of the gas internal flow path 357, and may be a position facing the upper surface 55a of the outer peripheral plug 355. The auxiliary member 670 may have, in addition to or instead of the gas passage hole 670a, a gas passage hole at a position facing the side surface of the outer peripheral plug 355 (that is, at a position between the side surface of the outer peripheral plug 355 and the side surface of the recessed portion 63).

It suffices that the interior of the auxiliary member 670 allows gas to pass; for example, the auxiliary member 670 may omit the gas passage hole 670a and instead be formed as a porous body. For instance, by making the auxiliary member 670 a metal porous body (porous metal), the auxiliary member 670 can be the member having conductive while also allowing gas to pass through its interior. The Auxiliary member 470 and the auxiliary member 570 may also allow gas to pass through their interiors, similar to the auxiliary member 670. For example, the auxiliary member 470 and the auxiliary member 570 may each have gas passage holes and/or be porous bodies.

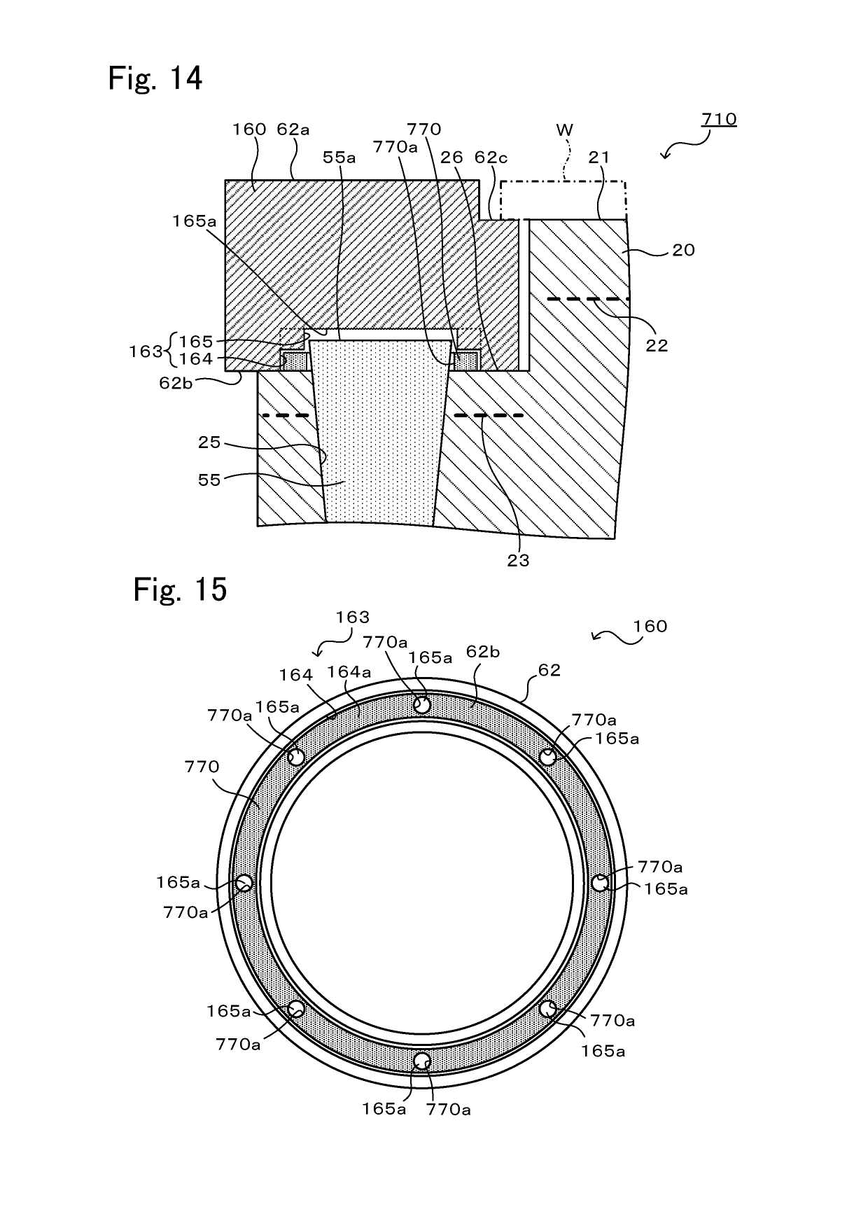

As shown in FIG. 11, the auxiliary member 470 was provided in plurality in a one-to-one correspondence with the plurality of outer peripheral plugs 55, but the present invention is not limited thereto. FIG. 14 is a partially enlarged longitudinal sectional view of a wafer placement table 710 according to a modification. FIG. 15 is a plan view of the focus ring 160 and an auxiliary member 770 of the wafer placement table 710 as seen from below. In FIG. 15, hatching is applied to the auxiliary member 770 for clarity of placement. In addition to the constituent elements of the wafer placement table 110 described above, the wafer placement table 710 further includes an auxiliary member 770 disposed between the focus ring 160 and the outer peripheral plugs 55. The auxiliary member 770 is a ring-shaped member disposed within the recessed portion 163 of the focus ring 160. The auxiliary member 770 is disposed within the annular groove 164 of the recessed portion 163 substantially concentrically with the annular groove 164. In the wafer placement table 710, a single auxiliary member 770 is disposed between the side surfaces of the portions of the plurality of outer peripheral plugs 55 that are positioned in the annular groove 164 and the side surface of the annular groove 164 of the recessed portion 163. The auxiliary member 770 has a plurality of through holes 770a provided in a one-to-one correspondence with the plurality of outer peripheral plugs 55. Each outer peripheral plug 55 is disposed inside a corresponding one of the through holes 770a. Accordingly, the auxiliary member 770 surrounds the periphery of the side surface of the portion of each outer peripheral plug 55 that is disposed within the recessed portion 163. The presence of this auxiliary member 770 allows the auxiliary member 770 to fill the gap between the focus ring 160 and the outer peripheral plugs 55 within the recessed portion 163. As a result, the volume of the space between the side surface of each outer peripheral plug 55 and the side surface of the recessed portion 163 within the recessed portion 163 can be reduced. Therefore, discharge within the recessed portion 163 can be more effectively suppressed. In the wafer placement table 710 shown in FIG. 14, the diameter of the through holes 770a is smaller than the diameter of the hole portions 165 of the recessed portion 163, but the diameter of the through holes 770a may be larger than the diameter of the hole portions 165. Further, although the auxiliary member 770 is not present between the upper surface 55a of the outer peripheral plug 55 and the bottom surface 165a of the recessed portion 163 in FIG. 14, it may be present there. For example, the through holes 770a may be formed as bottomed holes so that, like the auxiliary member 570, the auxiliary member 770 covers the entire upper end portion of the outer peripheral plug 55 that is disposed within the recessed portion 163. The auxiliary member 770 may also allow gas to pass through its interior, for example by having gas passage holes and/or by being a porous body.

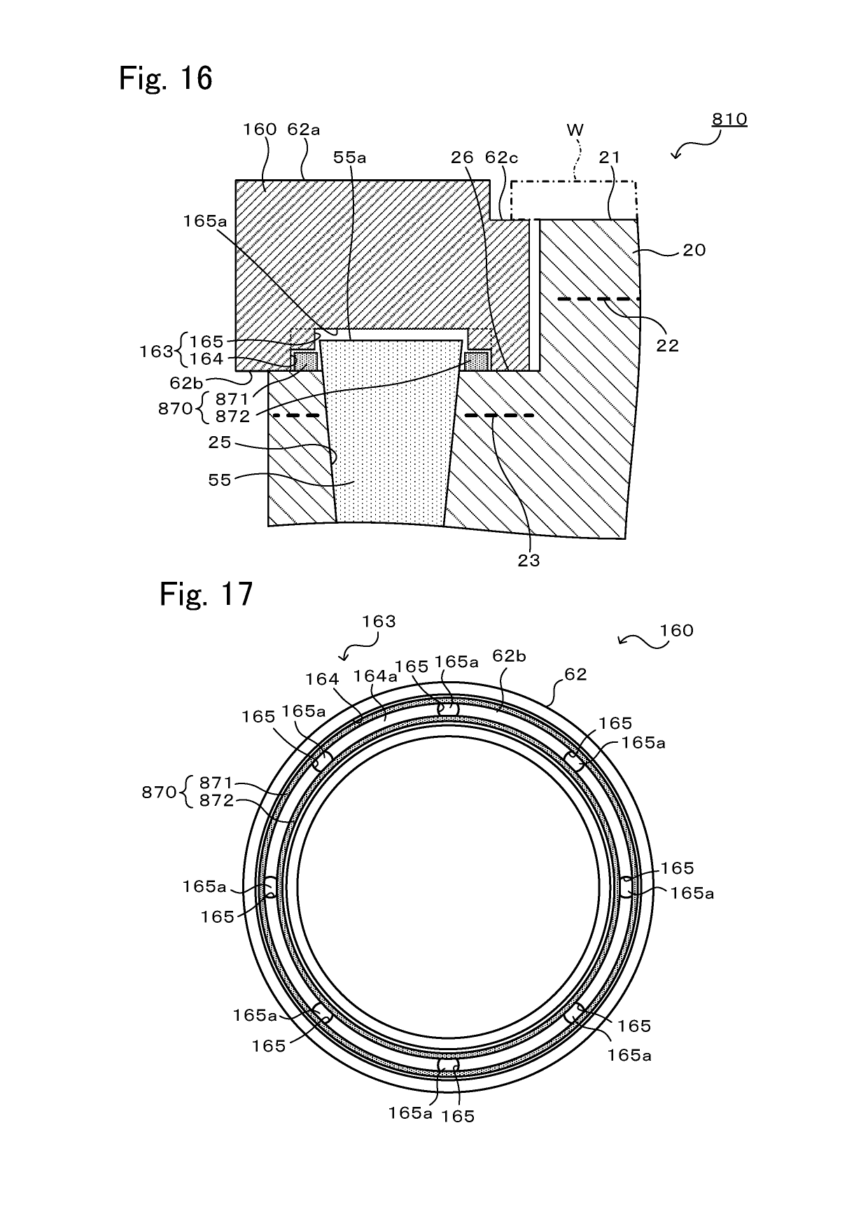

In place of the auxiliary member 770 shown in FIGS. 14 and 15, an auxiliary member 870 shown in FIGS. 16 and 17 may be employed. FIG. 16 is a partially enlarged longitudinal sectional view of a wafer placement table 810 according to a modification. FIG. 17 is a plan view of the focus ring 160 and an auxiliary member 870 of the wafer placement table 810 as seen from below. In FIG. 17, hatching is applied to the auxiliary member 870 for clarity of placement. In addition to the constituent elements of the wafer placement table 110 described above, the wafer placement table 810 further includes an auxiliary member 870 disposed between the focus ring 160 and the outer peripheral plugs 55. The auxiliary member 870 includes a first auxiliary member 871 and a second auxiliary member 872. The first auxiliary member 871 and the second auxiliary member 872 are each disposed between the side surface of the outer peripheral plugs 55 and the side surface of the annular groove 164 of the recessed portion 163. The first auxiliary member 871 is a ring-shaped member having an inner diameter equal to or larger than the diameter of a circumscribed circle that contacts the plurality of outer peripheral plugs 55. The second auxiliary member 872 is a ring-shaped member having an outer diameter equal to or smaller than the diameter of an inscribed circle that contacts the plurality of outer peripheral plugs 55. Each of the plurality of outer peripheral plugs 55 is disposed inside the first auxiliary member 871 and outside the second auxiliary member 872. With the auxiliary member 870 present, the gap between the focus ring 160 and the outer peripheral plugs 55 within the recessed portion 163 can be filled by the auxiliary member 870. Consequently, the volume of the space between the side surface of each outer peripheral plug 55 and the side surface of the recessed portion 163 within the recessed portion 163 can be reduced. Therefore, discharge within the recessed portion 163 can be more effectively suppressed. As is apparent from FIGS. 16 and 17, in the wafer placement table 810, the inner diameter of the first auxiliary member 871 is smaller than the diameter of a circumscribed circle that contacts the plurality of hole portions 165 of the recessed portion 163, but the inner diameter of the first auxiliary member 871 may be larger than the diameter of this circumscribed circle. Similarly, in the wafer placement table 810, the outer diameter of the second auxiliary member 872 is larger than the diameter of an inscribed circle that contacts the plurality of hole portions 165 of the recessed portion 163, but the outer diameter of the second auxiliary member 872 may be smaller than the diameter of this inscribed circle. The auxiliary member 870 may also allow gas to pass through its interior, for example by having gas passage holes and/or by being a porous body.

What is claimed is:

1. A wafer placement table comprising:
a ceramic body having a wafer placement surface and a focus ring placement surface located radially outside the wafer placement surface, the ceramic body having an electrode built therein;
a focus ring having conductive and placed on the focus ring placement surface;
a plug disposition hole located below the focus ring and penetrating the ceramic body; and
a plug provided in the plug disposition hole and allowing gas to pass through an interior thereof,
wherein the focus ring has a lower surface, and the lower surface has a recessed portion for pooling gas at a position opposed to the plug, and
an upper surface of the plug is disposed within the recessed portion and is located at a position higher than the lower surface of the focus ring.

2. The wafer placement table according to claim 1,
wherein a bottom surface of the recessed portion is at a position lower than the wafer placement surface.

3. The wafer placement table according to claim 1, wherein the recessed portion includes an annular groove provided radially outside the wafer placement surface,
the plug disposition hole and the plug are each provided in plurality below the focus ring, and
the upper surface of each of the plurality of plugs is disposed within the recessed portion.

4. The wafer placement table according to claim 3,
wherein the recessed portion includes one or more hole portions having a width narrower than that of the annular groove and having a bottom surface located higher than a bottom surface of the annular groove, and
the upper surface of each of the plurality of plugs is disposed within the one or more hole portions.

5. The wafer placement table according to claim 4,
wherein the one or more hole portions are provided in plurality in correspondence with each of the plurality of plugs, and
the upper surface of each of the plurality of plugs is disposed within a corresponding one of the hole portions.

6. The wafer placement table according to claim 1, wherein the plug has a hole in the upper surface thereof, and
the focus ring has a protruding portion that protrudes downward within the recessed portion and is inserted into the hole.

7. The wafer placement table according to claim 1, further comprising:
an auxiliary member disposed between a side surface of a portion of the plug that is disposed within the recessed portion and a side surface of the recessed portion.

8. The wafer placement table according to claim 7,
wherein the auxiliary member is also present between the upper surface of the plug and a bottom surface of the recessed portion.

9. The wafer placement table according to claim 7,
wherein the auxiliary member allows gas to pass through an interior thereof.

10. The wafer placement table according to claim 7,
wherein the auxiliary member has conductive and is electrically continuous with the focus ring.

11. The wafer placement table according to claim 7,
wherein the plug disposition hole and the plug are each provided in plurality below the focus ring, and
the recessed portion and the auxiliary member are each provided in plurality in one-to-one correspondence with the plurality of plugs.
